(19) United States
(12) Patent Application Publication
(10) Pub. No.: US 2024/0310456 A1
(43) Pub. Date: Sep. 19, 2024

(54) DETERMINING A STATE OF A FUSE

(71) Applicant: Caterpillar Inc., Peoria, IL (US)

(72) Inventors: Srihari Ranganathan N, Coimbatore (IN); V. Kameswara Kiran Kumar Rajala, Kakinada (IN); Stephen Adam Edwards, Peterborough (GB); James Kieran McCloskey, Stanford (GB); Joseph Oluwagbeminiyi Oyekan, Peterborough (GB)

(73) Assignee: Caterpillar Inc., Peoria, IL (US)

(21) Appl. No.: 18/184,985

(22) Filed: Mar. 16, 2023

(51) Int. Cl. G01R 31/74; G01R 19/25; H01M 10/42; H02J 7/00

(52) U.S. Cl. CPC G01R 31/74; G01R 19/2506; H01M 10/425; H02J 7/0031

(57) ABSTRACT

A method for determining a state of a fuse in a battery pack is provided. The battery pack comprises a first string comprising a first string fuse; at least one parallel arrangement comprising a battery cell and a resistor; and a first ammeter. The parallel arrangement is configured to be changeable between a connected state wherein the resistor is connected in parallel to the battery cell and a disconnected state wherein the resistor is disconnected from the battery cell. A second string comprising at least one battery cell is connected in parallel to the first string. The method comprises changing the at least one parallel arrangement of the first string to the connected state, and measuring a current passing through the first string. In an event that the change in the first current does not exceed a threshold, the first string fuse is in a blown state.

### FIELD OF THE DISCLOSURE

The disclosure relates to the field of battery management. More particularly, the present disclosure relates to a system and a method for determining a state of a fuse within a battery pack.

### BACKGROUND

It is known for battery packs to comprise a plurality of strings connected in parallel, wherein each string comprises one or more cells. The battery management system (BMS) is known to calculate the current limit of a battery pack based on the number of strings that are online. In some architectures and applications, each string comprises a string contactor. In these cases, the BMS is able to determine how many strings are online, and the current levels may be adjusted. However, in some architectures and applications the strings do not comprise string contactors, so the BMS assumes all strings are online and does not detect if string fuses are intact or in a blown state. In the event of a blown fuse on a string, the current limits are not adjusted for the string being offline and there is a risk of overloading the remaining active strings.

U.S. Pat. No. 10,135,243, referred to herein as the '243 reference, describes a method of determining fuse blowout based on how often cell equalisation or balancing occurs. The '243 reference assumes that the likelihood of cell balancing occurring is higher when there is a blown cell fuse. The method of the '243 reference requires one fuse per cell, and is therefore usable only for cells connected in parallel. The method of the '243 reference requires tracking the frequency of cell balancing over a period of time, where frequency of cell balancing is the number of times discharging for cell balancing occurs in a certain time period, or a cumulative duration of discharging for cell balancing in a certain time period. The method of the '243 reference cannot facilitate a rapid determination of the state of the fuses. Furthermore, the method of the '243 reference is usable in determining the state of the fuses only when the battery is running (in closed circuit) so cannot allow the fuses to be determined before use of the battery.

It is an object of the present disclosure to help manufacturers and users of battery packs determine the state of the fuses rapidly, reliably and cost-effectively.

### SUMMARY

According to first aspect of the present disclosure, a method is provided for determining a state of a fuse in a battery pack. The battery pack comprises a first string comprising a first string fuse. The first string further comprises at least one parallel arrangement comprising a battery cell and a resistor, wherein the parallel arrangement is configured to be changeable between a connected state wherein the resistor is connected in parallel to the battery cell; and a disconnected state wherein the resistor is disconnected from the battery cell. The first string further comprises a first ammeter, wherein the first string fuse, the at least one parallel arrangement and the first ammeter are connected in series. The battery pack further comprises a second string connected in parallel to the first string, the second string comprising at least one battery cell. The method comprises determining a state of the first string fuse by changing the at least one parallel arrangement of the first string to the connected state. The method further comprises measuring a first current passing through the first string using the first ammeter during a first time period after the at least one parallel arrangement is changed to the connected state. The method further comprises determining whether a change in the first current during the first time period is greater than a threshold current change. In an event that the change in the first current during the first time period does not exceed the threshold change, the method further comprises providing a notification that the first string fuse is in a blown state. In an event that the change in the first current during the first time period is greater than the threshold change, the first string fuse is determined to be intact.

In this way, it is possible to whether the first string fuse is in tact or broken by using a resistor to partially discharge a battery cell of the first string and measuring the current flow through the first string. In an event that the first string fuse is in tact, current will flow to compensate for the dissipated charge. In an event that the first string fuse is broken, no current will be able to flow. This allows a state of the fuse to be determined before the battery is connected to a load, since no power is required. Knowledge of a broken fuse or open circuit means that current limits of the battery pack or multi-pack battery can be adjusted to avoid overloading the other strings and/or any other battery packs. This method allows a rapid and reliable determination of the state of the first string fuse. Furthermore, the method may allow a state of a string fuse to be determined for a string having one string fuse and more than one battery cell.

According to a second aspect of the present disclosure, a battery management system is provided wherein the battery management system is configured to carry out the method of the first aspect of the disclosure.

According to a third aspect of the present disclosure, a machine is provided wherein the machine comprises an electrical load and a battery pack coupled to the electrical load.

The battery pack comprises a first string comprising a first string fuse. The first string further comprises at least one parallel arrangement comprising a battery cell and a resistor, wherein the parallel arrangement is configured to be changeable between a connected state wherein the resistor is connected in parallel to the battery cell; and a disconnected state wherein the resistor is disconnected from the battery cell. The first string further comprises a first ammeter, wherein the first string fuse, the at least one parallel arrangement and the first ammeter are connected in series. The battery pack further comprises a second string connected in parallel to the first string, the second string comprising at least one battery cell. The machine further comprises a battery management system configured to carry out the method of the first aspect of the disclosure.

According to a fourth aspect of the disclosure, a method is provided of detecting the presence or absence of an open circuit in a battery pack. The battery pack comprises a first string comprising a first string fuse. The first string further comprises at least one parallel arrangement comprising a battery cell and a resistor, wherein the parallel arrangement is configured to be changeable between a connected state wherein the resistor is connected in parallel to the battery cell; and a disconnected state wherein the resistor is disconnected from the battery cell. The first string further comprises a first ammeter, wherein the first string fuse, the at least one parallel arrangement and the first ammeter are connected in series. The battery pack further comprises a second string connected in parallel to the first string, the second string comprising at least one battery cell. The method comprises changing the at least one parallel arrangement to the connected state. The method further comprises measuring a first current passing through the first string using the first ammeter during a first time period after the at least one parallel arrangement is changed to the connected state. The method further comprises determining whether a change in the first current during the first time period is greater than a threshold current change. In an event that the change in the first current during the first time period does not exceed the threshold change, the method further comprises providing a notification that the first string comprises a break in the circuit. In an event that the change in the first current during the first time period is greater than the threshold change, the first string is determined to be intact.

### BRIEF DESCRIPTION OF THE DRAWINGS

A specific embodiment of the disclosure will now be described, by way of example only, with reference to the accompanying drawings in which:

FIG. 1 shows a circuit diagram of a battery pack suitable for carrying out a method according to an embodiment of the present disclosure.

FIG. 2 shows a flow chart illustrating a method for determining a state of a fuse according to an embodiment of the present disclosure.

FIG. 3 shows circuit diagrams of the battery pack of FIG. 1, wherein the first string fuse is in tact. FIG. 3A shows a circuit diagram for when the parallel arrangement of the first string in a disconnected state. FIG. 3B shows a circuit diagram for when the parallel arrangement of the first string in a connected state. FIG. 3C illustrates the current flow while the parallel arrangement of the first string in a connected state.

FIG. 4 shows circuit diagrams of a battery pack of FIG. 1, wherein the first string fuse is broken. FIG. 4A shows a circuit diagram for when the parallel arrangement of the first string in a disconnected state. FIG. 4B shows a circuit diagram for when the parallel arrangement of the first string in a connected state. FIG. 4C illustrates the lack of current flow while the parallel arrangement of the first string in a connected state.

FIG. 5 shows a circuit diagram of a battery pack suitable for carrying out a method according to an embodiment of the present disclosure, wherein the first string comprises more than one parallel arrangement.

FIG. 6 shows a circuit diagram of a battery pack suitable for carrying out a method according to an embodiment of the present disclosure, wherein the second string comprises a parallel arrangement.

FIG. 7 shows a circuit diagram of a battery pack suitable for carrying out a method according to an embodiment of the present disclosure, wherein battery pack is connected to a load.

FIG. 8A shows a schematic circuit diagram of six strings of a battery pack according to an embodiment of the present disclosure. FIG. 8B shows the current flow through six strings of a battery pack such as that shown in FIG. 8A during a method of determining the state of the first string fuse according to an embodiment of the present disclosure.

FIG. 9 shows a schematic circuit diagram of a battery pack connected to a battery management system according to an embodiment of the present disclosure.

FIG. 10 shows a schematic circuit diagram of a battery pack connected to a battery management system and a machine according to an embodiment of the present disclosure.

FIG. 11 shows a flowchart illustrating a method of detecting the presence or absence of an open circuit in a battery pack, according to an embodiment of the present disclosure.

### DETAILED DESCRIPTION

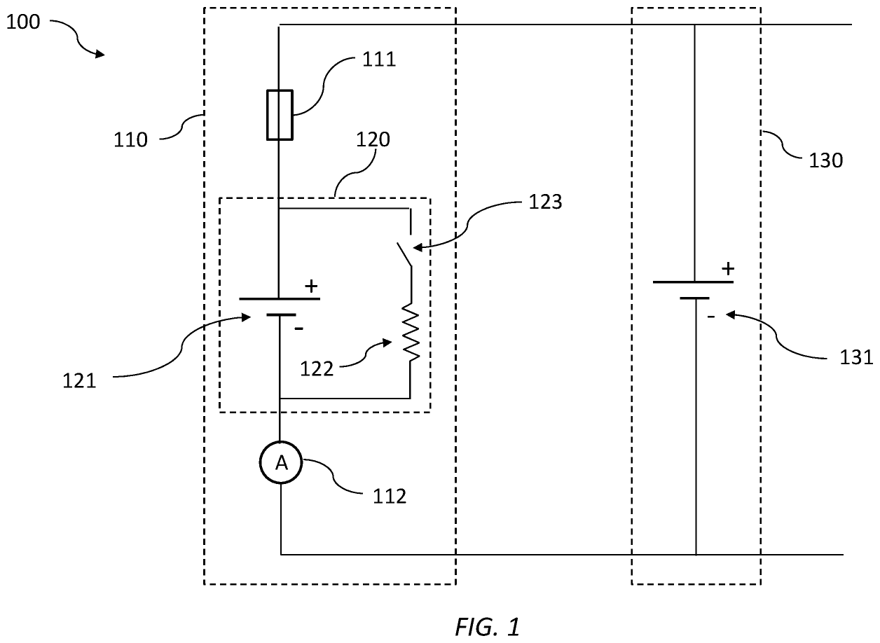

According to an embodiment of the present disclosure, a method for determining a state of a fuse in a battery pack is provided. With reference to FIG. 1, an example of a battery pack 100 is illustrated. The battery pack 100 comprises a first string 110. The first string 110 comprises a first string fuse 111 and a first ammeter 112. The first string 110 further comprises at least one parallel arrangement 120 comprising a battery cell 121 and a resistor 122. The parallel arrangement 120 is configured to be changeable between a connected state and a disconnected state (and vice versa). In the connected state the resistor 122 is connected in parallel to the battery cell 121, and in the disconnected state the resistor 122 is disconnected from the battery cell 121. An example is indicated in FIG. 1 whereby the parallel arrangement is changeable between the connected state and the disconnected state by actuating a switch 123. The switch 123 is shown as being open in FIG. 1. When the parallel arrangement 120 is in the disconnected state, the battery cell 121 is still connected in the first string 110, but the battery cell 121 does not have a resistor 122 connected across it. The first string fuse 111, the at least one parallel arrangement 120 and the first ammeter 112 are connected in series. The battery pack 100 further comprises a second string 130, the second string 130 comprising at least one battery cell 131.

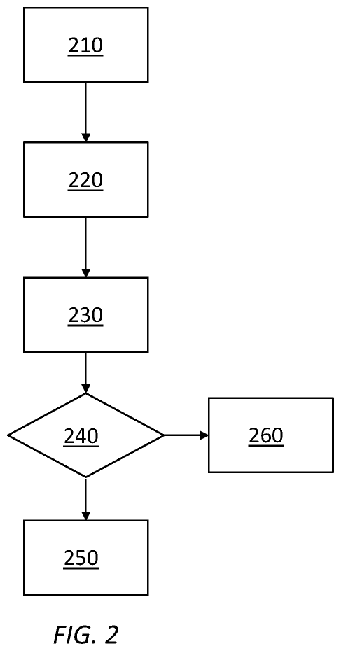

With reference to FIG. 2, the method for determining a state of the first string fuse 111 comprises changing the at least one parallel arrangement 120 of the first string 110 to the connected state at step 210. For example, switch 123 may be closed. At step 220, a first current passing through the first string 110 is measured using the first ammeter 112 during a first time period. The first time period occurs after the at least one parallel arrangement 120 is changed to the connected state. At step 230 it is determined whether a change in the first current during the first time period is greater than a threshold current change. In an event that the change in the first current during the first time period does not exceed the threshold change at step 240, the method comprises providing a notification that the first string fuse 111 is in a blown state at step 250. In an event that the change in the first current during the first time period is greater than the threshold change at step 240, the first string fuse 111 is determined to be intact at step 260.

After the first time period, the at least one parallel arrangement may be changed to the disconnected state, for example by opening switch 123.

Providing a notification that the first string fuse 111 is in a blown state may comprise one or more of notifying an operator, triggering an alarm or sound, turning on a light, providing a message on a display, recording the notification, communicating the notification to a server, or other means of notification. In an event that the change in the first current during the first time period does not exceed the threshold change, the method may further comprise taking the first string offline.

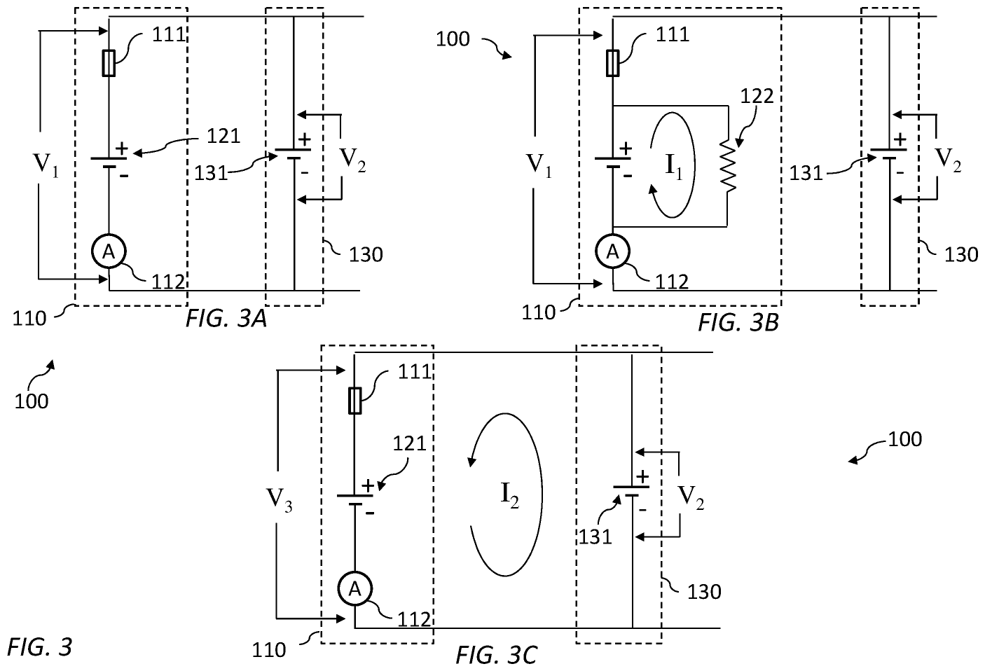

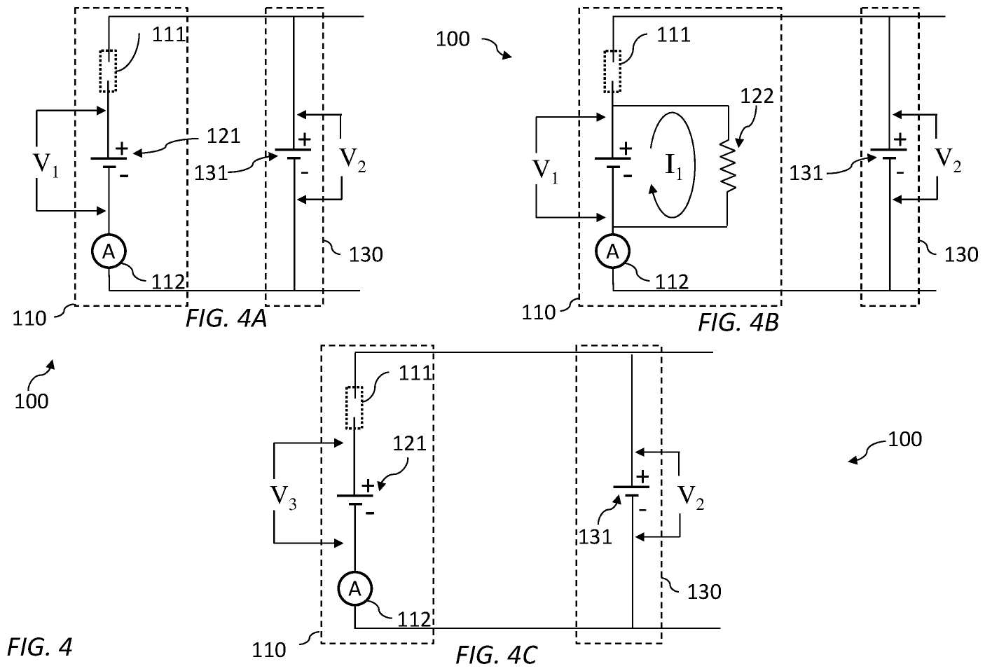

When the parallel arrangement 120 is changed to be in the connected state at step 210, current flows within the parallel arrangement 120 as the battery cell 121 discharges through the resistor 122. As the first string 110 and the second string 130 are in parallel, the voltage across each string must balance. In order to achieve this, current flows to transfer charge from the battery cell 131 of the second string to the battery cell 121 of the first string. This can occur only if the first string 110 is complete (i.e. the first string fuse 111 is in tact), so that the first and second strings 110, 130 form a complete circuit. In an event that the first string fuse is not in tact, the current flow to transfer charge from the battery cell 131 of the second string to the battery cell 121 of the first string cannot occur, since there is no complete circuit between the first and second strings 110, 130. This will be described in more detail with reference to FIGS. 3 and 4.

FIG. 3 shows the battery pack 100 with the first string fuse 111 in tact. FIG. 3A shows the circuit of the battery pack 100 when the parallel arrangement 120 is in the disconnected state, such that the resistor 122 is not connected in parallel with the first battery cell 121. The voltage across the first string 110 is V₁ and the voltage across the second string is V₂. As the first string 110 is in parallel with the second string 130, V₁=V₂. At step 210, the parallel arrangement 120 is changed to the connected state, such that the resistor 122 is connected in parallel with the first battery cell 121 as shown in FIG. 3B. This creates a closed loop, and current I₁ flows, dissipating energy across the resistor 122 and reducing the voltage of the first battery cell 121. With reference to FIG. 3C, the potential difference across the first string 110 is now V₃<V₁. The first string fuse 111 is in tact, so there is a closed loop between the first string 110 and the second string 130. Current I₂ flows to compensate for the imbalance in potential difference, such that the first battery cell 121 is charged by the second battery cell 131. V₃ is increased and V₂ is decreased, until the potential difference across the first string 110 is equal to the potential difference across the second string 130. The first ammeter 112 measures this current flow during the first time period.

FIG. 4 shows the battery pack 100 with the first string fuse 111 broken. FIG. 4A shows the circuit of the battery pack 100 when the parallel arrangement 120 is in the disconnected state, such that the resistor 122 is not connected in parallel with the first battery cell 121. The voltage across the first battery cell 121 is V₁ and the voltage across the second string is V₂. At step 120, the parallel arrangement 120 is changed to the connected state, such that the resistor 122 is connected in parallel with the first battery cell 121 as shown in FIG. 4B. This creates a closed loop, and current I₁ flows, dissipating energy across the resistor 122 and reducing the voltage of the first battery cell 121. With reference to FIG. 4C, the potential difference across the first battery cell 121 is now V₃<V₁. However, the first string fuse 111 is broken, so there is no closed loop between the first string 110 and the second string 130. Current cannot flow to compensate for the imbalance in potential difference between the first and second strings 110, 130, so there is no current measured on the first ammeter 112 during the first time period.

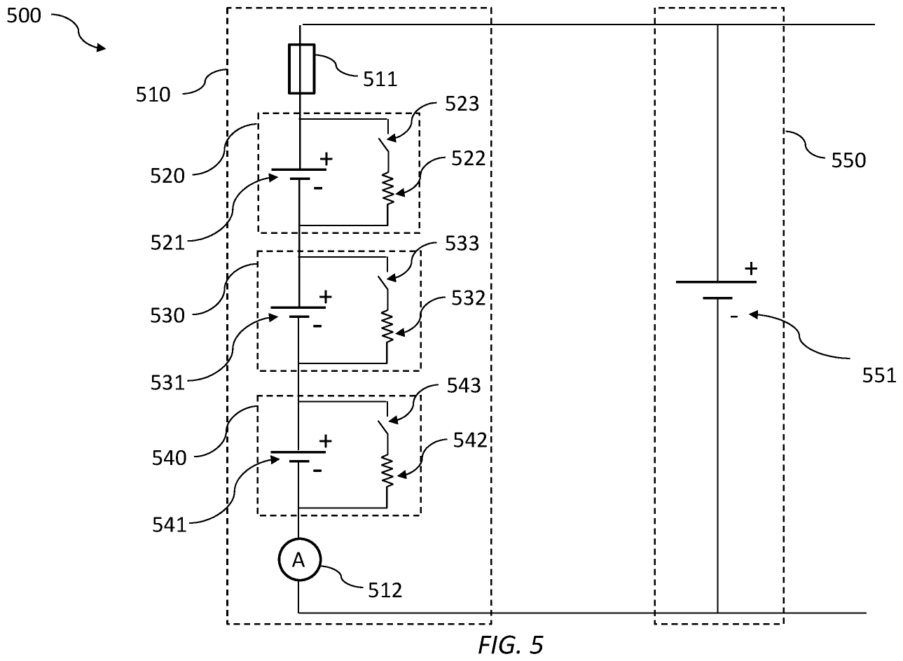

In certain embodiments, the first string may comprise two or more parallel arrangements connected in series. Each parallel arrangement comprises a battery cell and a resistor and each parallel arrangement is configured to be changeable between a connected state, wherein the resistor is connected in parallel to the battery cell, and a disconnected state, wherein the resistor is disconnected from the battery cell. With reference to FIG. 5, a battery pack 500 is illustrated, wherein the first string 510 comprises three parallel arrangements 520, 530 and 540. This an example, and the first string may comprise more than three parallel arrangements or fewer than three parallel arrangements. The battery pack 500 comprises a first string 510. The first string 510 comprises a first string fuse 511 and a first ammeter 512. The first string 510 further comprises a first parallel arrangement 520 comprising a battery cell 521 and a resistor 522. The parallel arrangement 520 is configured to be changeable between a connected state and a disconnected state. In the connected state the resistor 522 is connected in parallel to the battery cell 521, and in the disconnected state the resistor 522 is disconnected from the battery cell 521. An example is indicated in FIG. 5 whereby the parallel arrangement is changeable between the connected state and the disconnected state by actuating a switch 523. The switch 523 is shown as being open in FIG. 1. The first string 510 further comprises a second parallel arrangement 530 comprising a battery cell 531 and a resistor 532. The parallel arrangement 530 is configured to be changeable between a connected state and a disconnected state. In the connected state the resistor 532 is connected in parallel to the battery cell 531, and in the disconnected state the resistor 532 is disconnected from the battery cell 531. The first string 510 further comprises a third parallel arrangement 540 comprising a battery cell 541 and a resistor 542. The parallel arrangement 540 is configured to be changeable between a connected state and a disconnected state. In the connected state the resistor 542 is connected in parallel to the battery cell 541, and in the disconnected state the resistor 542 is disconnected from the battery cell 541. The first string fuse 511, the first parallel arrangement 520, the second parallel arrangement 530, the fourth parallel arrangement 540 and the first ammeter 512 are connected in series. The battery pack 500 further comprises a second string 550, the second string 550 comprising at least one battery cell 551.

The method described with reference to FIG. 2 may be carried out for the battery pack of FIG. 5. Step 210 may comprise changing each of the first, second and third parallel arrangements 520, 530 and 540 to the connected state at the same time, such that each of the battery cells 521, 522 and 523 start to discharge at the same time. In this way, each of the battery cells 521, 522 and 523 may discharge by a similar amount during the method. Similarly, in embodiments where the first string comprises a different number of parallel arrangements, the step 210 comprises changing each of the parallel arrangements to the connected state at the same time such that the battery cell of each parallel arrangement discharges at the same time. In other embodiments where the first string comprises a different number of parallel arrangements, step 210 may comprise changing each of the parallel arrangements to the connected state sequentially. In other embodiments where the first string comprises a different number of parallel arrangements, step 210 may comprise changing one or more of the parallel arrangements to the connected state, while the other parallel arrangement(s) remain in the disconnected state.

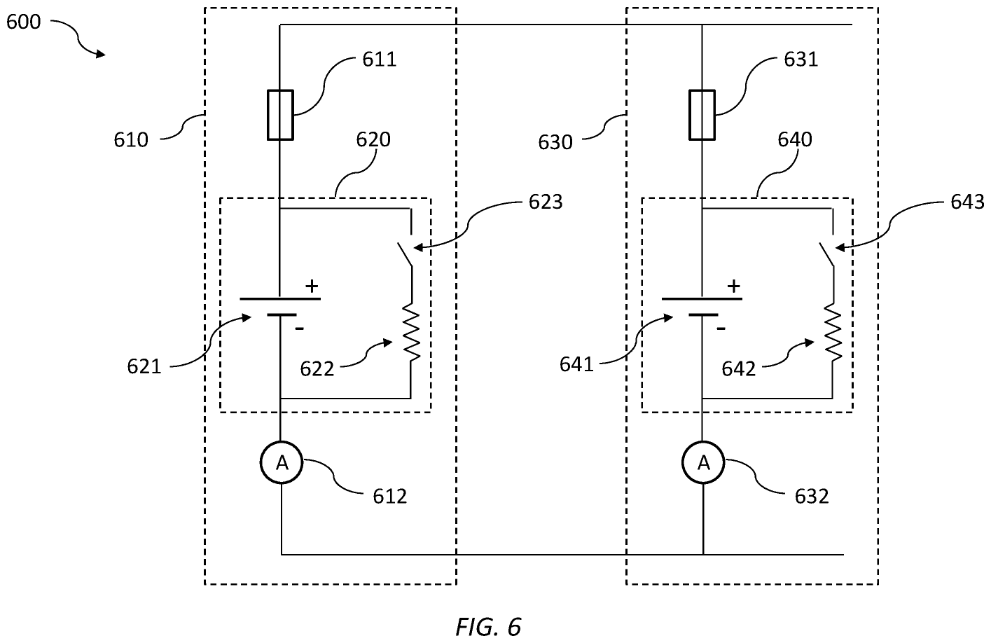

In certain embodiments, the second string of the battery pack may further comprise a second string fuse, a second ammeter and at least one parallel arrangement comprising a battery cell and a resistor. With reference to FIG. 6, a battery pack 600 comprises a first string 610. The first string 610 comprises a first string fuse 611 and a first ammeter 612. The first string 610 further comprises at least one parallel arrangement 620 comprising a battery cell 621 and a resistor 622. The parallel arrangement 620 is configured to be changeable between a connected state and a disconnected state. In the connected state the resistor 622 is connected in parallel to the battery cell 621, and in the disconnected state the resistor 622 is disconnected from the battery cell 621. An example is indicated in FIG. 6 whereby the parallel arrangement is changeable between the connected state and the disconnected state by actuating a switch 623. The switch 623 is shown as being open in FIG. 6. The first string fuse 611, the at least one parallel arrangement 620 of the first string and the first ammeter 612 are connected in series. The battery pack 600 further comprises a second string 630. The second string 630 comprises a second string fuse 631 and a second ammeter 632. The second string 630 further comprises at least one parallel arrangement 640 comprising a battery cell 641 and a resistor 642. The parallel arrangement 640 is configured to be changeable between a connected state and a disconnected state. In the connected state the resistor 642 is connected in parallel to the battery cell 641, and in the disconnected state the resistor 642 is disconnected from the battery cell 641. An example is indicated in FIG. 6 whereby the parallel arrangement is changeable between the connected state and the disconnected state by actuating a switch 643. The switch 643 is shown as being open in FIG. 6. The second string fuse 631, the at least one parallel arrangement 640 of the second string, and the second ammeter 632 are connected in series.

In certain embodiments, the method of determining a state of a fuse of the battery pack 600 comprises determining a state of the first string fuse 611 and determining a state of the second string fuse 631. Determining a state of the first string fuse 611 comprises changing the at least one parallel arrangement 620 of the first string 610 to the connected state. For example, switch 623 may be closed. The at least one parallel arrangement 640 of the second string 630 is in the disconnected state. A first current passing through the first string 610 is measured using the first ammeter 612 during a first time period. The first time period occurs after the at least one parallel arrangement 620 of the first string 610 is changed to the connected state. It is determined whether a change in the first current during the first time period is greater than a threshold current change. In an event that the change in the first current during the first time period does not exceed the threshold change, the method comprises providing a notification that the first string fuse 611 is in a blown state. In an event that the change in the first current during the first time period is greater than the threshold change, the first string fuse 611 is determined to be intact. The at least one parallel arrangement 620 of the first string 610 is changed to the disconnected state. The method further comprises determining a state of the second string fuse 631. The at least one parallel arrangement 640 of the second string 630 is changed to the connected state. For example, switch 643 may be closed. The at least one parallel arrangement 620 of the first string 610 is in the disconnected state. A second current passing through the second string 630 is measured using the second ammeter 632 during a second time period. The second time period occurs after the at least one parallel arrangement 640 of the second string 630 is changed to the connected state. It is determined whether a change in the second current during the second time period is greater than a threshold current change. In an event that the change in the second current during the second time period does not exceed the threshold change, the method comprises providing a notification that the second string fuse 631 is in a blown state. In an event that the change in the second current during the second time period is greater than the threshold change, the second string fuse 631 is determined to be intact. The at least one parallel arrangement 640 of the second string 630 is changed to the disconnected state.

One or both of the first string 610 and the second string 630 may comprise more than one parallel arrangement, wherein the more than one parallel arrangements are connected in series.

In certain embodiments, the battery pack may further comprise at least one additional string connected in parallel to the first string and the second string. Each additional string may be similar to the first or second string, such that each additional string comprises a string fuse, an ammeter and at least one parallel arrangement comprising a battery cell and resistor. The at least one parallel arrangement is configured to be changeable between A connected state wherein the resistor is connected in parallel to the battery cell; and a disconnected state wherein the resistor is disconnected from the battery cell. The ammeter, the string fuse, the at least one parallel arrangement of each additional string are connected in series. For each additional string, the method further comprises determining a state of the string fuse of the additional string, using the method outlined above. Determining a state of the string fuse for a given string comprises changing the at least one parallel arrangement of that string to the connected state, wherein the parallel arrangements of all other strings are in the disconnected state. A current passing through the given string is measured using the ammeter of that string during a time period after changing the at least one parallel arrangement of that string to the connected state. It is determined whether a change in the current during the time period is greater than a threshold current change. In an event that the change in the current during the time period does not exceed the threshold change, the method comprises providing a notification that the string fuse of the additional string is in a blown state. In an event that the change in the current during the time period is greater than the threshold change, the string fuse of the additional string is determined to be intact. This may be repeated for each string.

In embodiments where the method comprises determining a state of a fuse of more than one string, determining the state of the fuse of each string may be carried out sequentially.

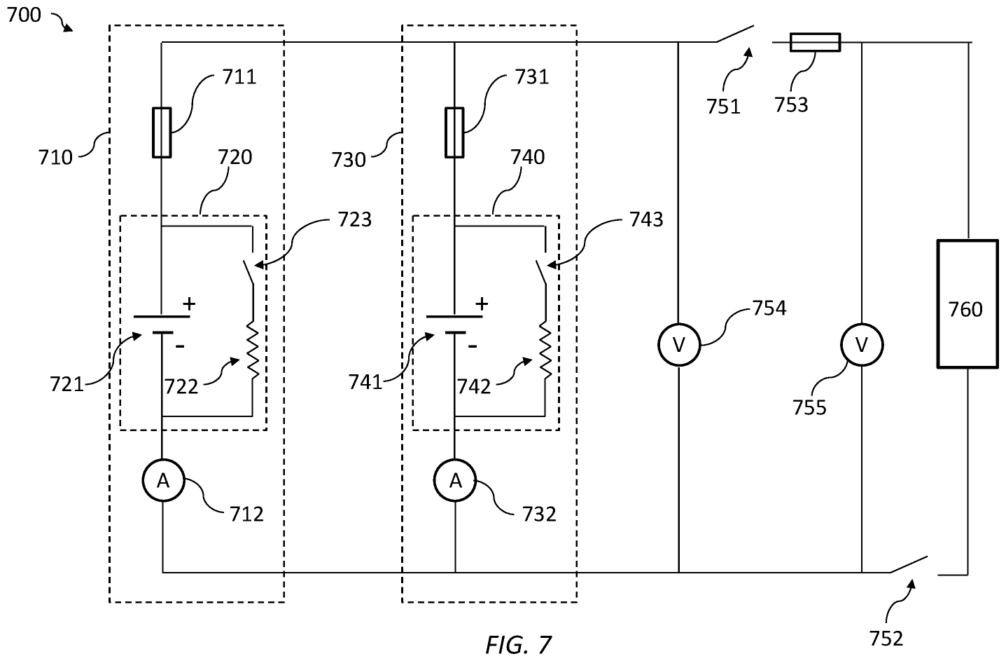

In certain embodiments, the methods outlined above may be carried out when the battery pack is in standby mode. There may be no load connected to the battery pack, such that the only closed circuits may be between strings of the battery pack or when the parallel arrangement(s) are in a connected state. The battery may be in closed circuit, to the extent that the fuse(s) are in tact, but any electrical loads do not draw current from the battery in a standby state. The methods outlined above may be carried out when a main contactor of the battery is open (such that the battery is disconnected from the load). For example, FIG. 7 shows a battery pack similar to that illustrated in FIG. 6, wherein the battery pack 700 is connectable to a load 760 via main contactors 751 and 752. The methods outlined above may be carried out when one or both of main contactors 751 and 752 may be open. In certain embodiments, main contactor 751 may comprise a positive contactor and main contactor 752 may comprise a negative contactor.

In certain embodiments, the battery pack may be configured to power an electric vehicle. The methods outlined above may be carried out at key on of the electric vehicle. The methods outlined above may be carried out at key off of the electric vehicle.

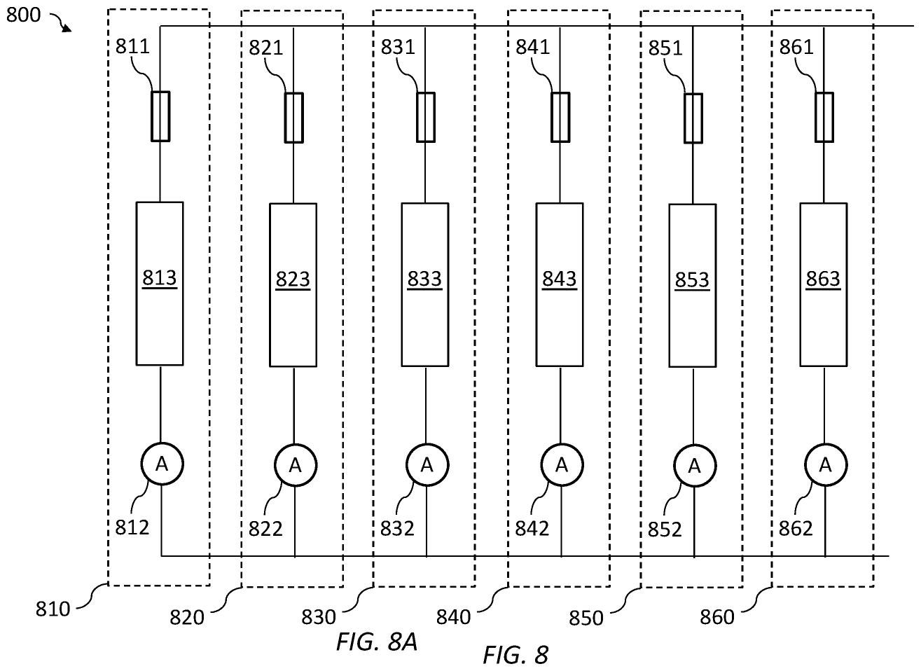

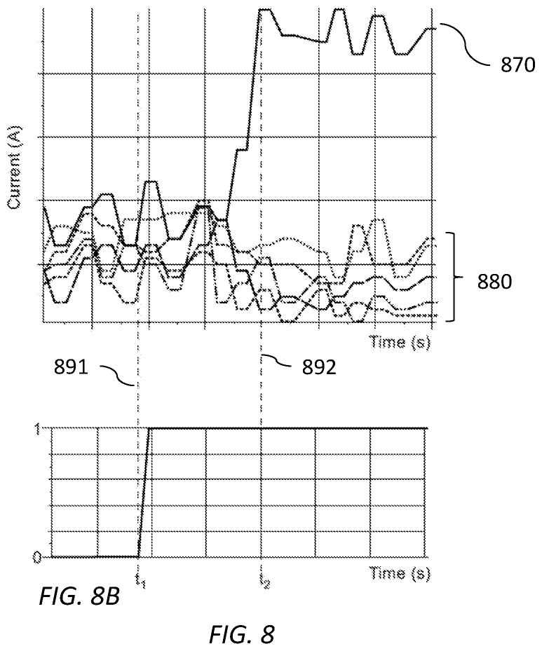

FIG. 8 shows an example of current measurements for six strings of a battery pack while carrying out a method according to an embodiment of the disclosure. FIG. 8A shows six strings 810, 820, 830, 840, 850 and 860 of a battery pack 800, wherein the six strings 810, 820, 830, 840, 850 and 860 are connected in parallel. Each string may comprise a string fuse 811, 821, 831, 841, 851 and 862. Each string further comprises an ammeter 812, 822, 832, 842, 852 and 862. Each string may further comprise one or more parallel arrangements, indicated by 813, 823, 833, 843, 853 and 863. The graphs illustrate current measurements while determining a state of a first string fuse 811 of a first string 810. The upper graph shows current plotted against time for each of the six strings. The lower graph shows the state of the parallel arrangement(s), wherein 1 is the connected state and 0 is the disconnected state. The upper and lower graphs are shown with the same time scale on the x-axes. At time t1, indicated by the left hand vertical dashed line 891, the parallel arrangement(s) of the first string are changed to be in the connected state. In this example, the first time period is between t1 and t2, where t2 is shown by the right hand vertical dashed line 892. The current passing through the first string is plotted as solid line 870. The current passing through the other five strings are shown as dashed and dotted lines (indicated by bracket 880). It can be seen that the current passing through the first string increases significantly during the first time period, indicating that current is flowing to compensate for the dissipated charge and so the first fuse is in tact.

The methods described above make use of a resistor that can be connected in parallel with a battery cell and disconnected from the battery cell. As discussed, these methods may be appropriate when the battery pack is not in use. Further methods may be used to determine a state of a fuse while the battery pack is running. One or more of the following methods may be used in addition to the methods described above. The following methods may be carried out continuously while the battery pack is running, or may be carried out periodically.

In certain embodiments, a method of determining a state of a string fuse of a battery pack while the battery pack is in use may comprise comparing the string current to a pack current. In an event that for a period of time longer than a threshold time the current of the battery pack is above a pack threshold and the current of the connected string is below a string threshold, the method further comprises notifying an operator that the string fuse of the string is in a blown state.

In certain embodiments, the battery pack may further comprise a battery pack fuse, such as the battery pack fuse 753 illustrated in FIG. 7. The method may further comprise determining a status of the battery pack fuse by comparing a bus voltage (or machine-side voltage) and a battery pack voltage when the battery pack is online (main contactors are closed). The bus voltage may be measured using voltmeter 755, and the battery pack voltage may be measured using voltmeter 754. In an event that a difference between the bus voltage and the battery pack voltage is above a voltage threshold for a period of time longer than a threshold time, the method further comprises providing a notification that the battery pack fuse is in a blown state.

In certain embodiments, the battery pack may further comprise a battery pack fuse and the battery pack may be included in a multi-pack battery comprising at least one additional battery pack. The method may further comprise determining a status of a battery pack fuse. For each battery pack, the method may comprise comparing a current of each connected battery pack of the multi-pack battery to a current of the multi-pack battery, wherein in an event that the current of the multi-pack battery is above a battery current threshold and the current of the battery pack is below a pack current threshold, the method further comprises providing a notification that the battery pack fuse is in a blown state.

The methods described herein determine the state of a fuse. The battery pack current limits may be determined by the number of connected strings of the battery pack. In an event that it is determined that a string fuse is in a blown state, the method may further comprise adjusting the current limit(s) for the battery pack, based on the number of strings that are online and do not have a blown fuse. Similarly, the current limit for a multi-pack battery may depend on the number of connected battery packs of the multi-pack batteries. In an event that a method determines that the battery pack fuse is in a blown state, the method may further comprise adjusting the current limit for the multi-pack battery.

The methods of determining the state of a string fuse described above comprise measuring a current during a time period, wherein the time period occurs after the at least one parallel arrangement of the string fuse is changed to the connected state. The time period may be triggered by the at least one parallel arrangement of the string fuse is changing to the connected state. The time period may begin when the least one parallel arrangement of the string fuse is changed to the connected state. The time period may begin at a fixed time after least one parallel arrangement of the string fuse is changed to the connected state. The time period may be a fixed length of time.

In certain embodiments, in an event that a fuse is found to be in tact by one of the above methods, no action may be taken. In other embodiments, in an event that a fuse is found to be in tact by one of the above methods, a user may be notified.

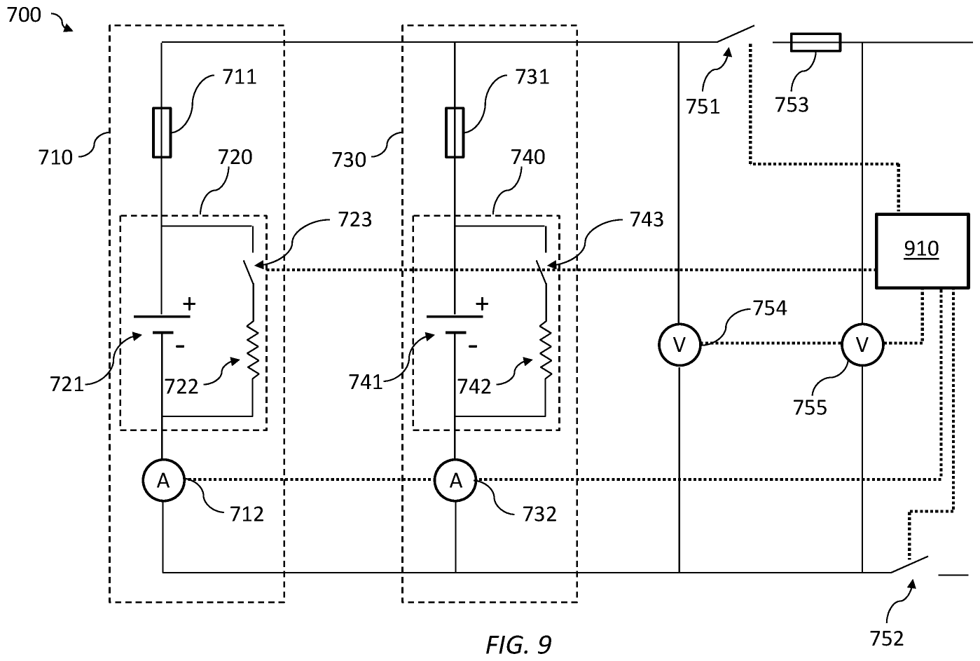

According to an embodiment, a battery management system is provided wherein the battery management system is configured to carry out the method of any preceding claim. With reference to FIG. 9, an example of a battery management system (BMS) 910 is shown for the battery pack 700 of FIG. 7. The BMS 910 may be communicably connected to the voltmeters 754 and 755 and the ammeters 712 and 732, wherein the BMS 910 is conjured to determine voltage and current from the voltmeters 754, 755 and the ammeters 712, 732, respectively. The BMS 910 may be communicably connected to each battery cell, and may be configured to sense cell voltage and temperature. The BMS 910 may be configured to control the state of each parallel arrangement, such that the BMS 910 is configured to change each parallel arrangement between the connected and disconnected state and vice versa. The BMS 910 may be further configured to control contactors 751 and 752. A BMS may be used with any of the battery packs described herein. The BMS may be configured to sense voltage and current, to control contactors, and to sense other properties of the battery cells.

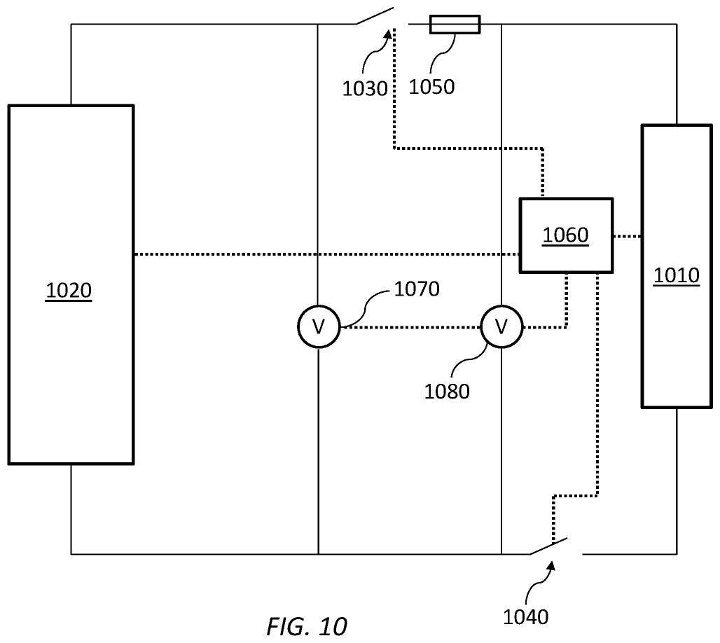

According to an embodiment, a machine is provided, wherein the machine comprises an electrical load and a battery pack coupled to the electrical load. For example, with reference to FIG. 10, the machine may comprise an electrical load 1010 and a battery pack 1020. The battery pack may be connected to or disconnected from the electrical load 1010 via main contactors 1030 and 1040, and may comprise a battery pack fuse 1050. A battery management system 1060 may be connected to the battery pack 1020, contactors 1030 and 1040, the electrical load 1010, and voltmeters 1070 and 1080. The battery pack 1020 comprises a first string comprising a first string fuse, a first ammeter and at least one parallel arrangement comprising a battery cell and a resistor. The parallel arrangement is configured to be changeable between a connected state wherein the resistor is connected in parallel to the battery cell; and a disconnected state wherein the resistor is disconnected from the battery cell. The first string fuse, the at least one parallel arrangement and the first ammeter are connected in series. The battery pack 1020 further comprises a second string connected in parallel to the first string, the second string comprising at least one battery cell. The battery management system 1060 is configured to carry out the method of any preceding claim. The battery pack 1020 may comprise any battery pack described herein.

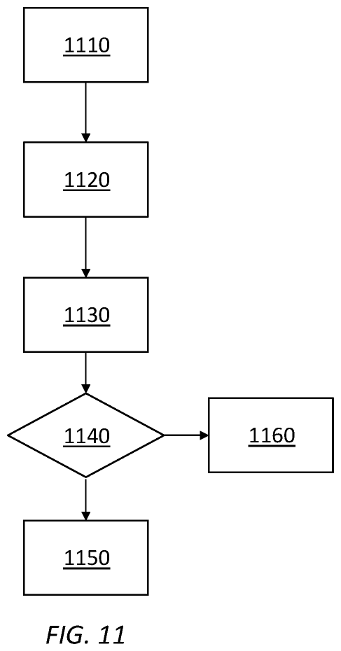

According to certain embodiments, the methods described above may be used to detect whether a circuit is open or closed. For example, there may be a fault other than a broken or short-circuited fuse that can result in an open circuit. For example, a switch or contactor may fail, or a wire may break. With reference to FIG. 11, according to certain embodiments a method may be provided of detecting the presence or absence of an open circuit in a battery pack. The battery pack comprises a first string comprising a first ammeter and at least one parallel arrangement comprising a battery cell and a resistor. The parallel arrangement is configured to be changeable between a connected state wherein resistor is connected in parallel to the battery cell; and a disconnected state wherein the resistor is disconnected from the battery cell. The at least one parallel arrangement and the first ammeter are connected in series. The battery pack further comprises a second string connected in parallel to the first string, the second string comprising at least one battery cell. The method comprises changing the at least one parallel arrangement to the connected state at step 1110. At step 1120 the method comprises measuring a first current passing through the first string using the first ammeter during a first time period after the at least one parallel arrangement is changed to the connected state At step 1130 the method comprises determining whether a change in the first current during the first time period is greater than a threshold current change. In an event that the change in the first current during the first time period does not exceed the threshold change at step 1140, the method comprises providing a notification that the first string comprises a break in the circuit at step 1150. In an event that the change in the first current during the first time period is greater than the threshold change at step 1140, the first string is determined to be intact at step 1160.

As described above, in certain embodiments a string of a battery pack may comprise more than one parallel arrangement in series. For instance, the battery pack 500 illustrates a first string comprising more than one parallel arrangement in series. The resistor of each parallel arrangement may be used as a balancing resistor. In an event that there is an imbalance between the more than one battery cells of the string, one or more of the parallel arrangements may be changed to the connected state. Changing a parallel arrangement to the connected state allows the battery cell of the parallel arrangement to discharge via the resistor. This can be used to reduce the state of charge of one or more of the battery cells until the state of charge of each battery cell is equal. For example, if a battery cell of a first parallel arrangement has a higher state of charge than the other battery cells of the string, the first parallel arrangement may be changed to the connected state such that the battery cell begins to discharge. When the battery cell of that string reaches the state of charge of the other battery cells of that string, the parallel arrangement may be changed to the disconnected state. These balancing resistors may be already present in battery packs, and may be implemented to carry out the methods described herein for determining the state of the string fuse.

### INDUSTRIAL APPLICABILITY

The methods described herein comprise determining a state of the first string fuse by changing the at least one parallel arrangement of the first string to the connected state. Changing a parallel arrangement to the connected state has the effect of creating a closed circuit including the resistor and the battery cell of the parallel arrangement, such that energy from the battery cell is dissipated via the resistor. The potential difference of the first string decreases, as the battery cell of each of the at least one parallel arrangements discharges. This may be achieved using existing resistors in a battery pack, since many battery packs comprise resistors in parallel with each battery cell. For instance, these resistors may be used for cell balancing.

The methods described herein further comprise measuring a first current passing through the first string using the first ammeter during a first time period after the at least one parallel arrangement is changed to the connected state. If the first string is in tact then it is connected in a parallel circuit with at least one other string. As the potential difference of the first string has decreased, current will flow to increase the potential difference of the first string (i.e. charge the battery cell(s) of the first string) such that the potential differences of the strings are equal. If the first string is not in tact, current will not be able to flow to compensate for the dissipation. Therefore, whether or not an increase in current is measured provides information as to whether the first string is in tact. In this way, the state of the first string fuse may be determined using the existing string ammeter, which is present in many battery packs and is monitored by a battery management system.

This allows a state of the fuse to be determined before the battery is connected to a load, since no power is required. In an event that a fuse is determined to be broken, the current limits for the battery pack or any other battery pack may be adjusted before the battery is connected to a load, preventing overloading the other strings and/or any other battery packs. The above methods allow a rapid and reliable determination of the state of the first string fuse. Furthermore, the method may allow a state of a string fuse to be determined for a string having one string fuse and more than one battery cell, so only one fuse is required per string.

In certain embodiments, the methods described herein may be used for a vehicle or work machine. The methods of determining a state of a fuse may be carried out at key ON of the vehicle or machine, such that in an event that the fuse is broken action may be taken before the load of the vehicle or machine is connected to the battery pack. In an event that a fuse of a string is broken, the string may be taken offline and the current limit of the battery pack may be adjusted, allowing the vehicle or machine to be safely used without losing operation time. An operator may be notified, either locally or remotely, such that maintenance may be carried out on the battery to remedy the broken fuse or open circuit. Otherwise, the issue may be logged such that during routine maintenance the broken fuse or open circuit may be fixed.

1. A method for determining a state of a fuse in a battery pack, wherein the battery pack comprises:
a first string comprising:
a first string fuse;
at least one parallel arrangement comprising a battery cell and a resistor, wherein the parallel arrangement is configured to be changeable between:
a connected state wherein the resistor is connected in parallel to the battery cell; and
a disconnected state wherein the resistor is disconnected from the battery cell; and
a first ammeter, wherein the first string fuse, the at least one parallel arrangement and the first ammeter are connected in series; and
a second string connected in parallel to the first string, the second string comprising at least one battery cell;
the method comprising determining a state of the first string fuse by:
changing the at least one parallel arrangement of the first string to the connected state;
measuring a first current passing through the first string using the first ammeter during a first time period after the at least one parallel arrangement is changed to the connected state;
determining whether a change in the first current during the first time period is greater than a threshold current change; and
in an event that the change in the first current during the first time period does not exceed the threshold change, providing a notification that the first string fuse is in a blown state;
wherein in an event that the change in the first current during the first time period is greater than the threshold change, the first string fuse is determined to be intact.

2. The method of claim 1, wherein the first string comprises at least two parallel arrangements connected in series, wherein each parallel arrangement comprises a battery cell and a resistor and wherein each parallel arrangement is configured to be changeable between a connected state wherein resistor is connected in parallel to the battery cell and a disconnected state wherein the resistor is disconnected from the battery cell.

3. The method of claim 2, wherein the method comprises changing the at least two parallel arrangements to the connected state.

4. The method of claim 1, wherein the second string comprises:
a second string fuse;
at least one parallel arrangement comprising a battery cell and a resistor, wherein the parallel arrangement is configured to be changeable between:
a connected state wherein the resistor is connected in parallel to the battery cell; and
a disconnected state wherein the resistor is disconnected from the battery cell; and
a second ammeter, wherein the second string fuse, the at least one parallel arrangement of the second string and the second ammeter are connected in series;
the method further comprising determining a state of the second string fuse by:
changing the at least one parallel arrangement of the second string to the connected state;
measuring a second current passing through the first string using the second ammeter during a second time period after the at least one parallel arrangement of the second string is changed to the connected state;
determining whether a change in the second current during the second time period is greater than a threshold current change;
in an event that the change in the second current during the second time period does not exceed the threshold change, providing a notification that the second string fuse is in a blown state; and
wherein in an event that the change in the second current during the second time period is greater than the threshold change, the second string fuse is determined to be intact.

5. The method of claim 4, wherein:
the battery pack further comprises at least one additional string connected in parallel to the first string and the second string, each additional string comprising:
a string fuse;
at least one parallel arrangement comprising a battery cell and a resistor, wherein the parallel arrangement is configured to be changeable between:
a connected state wherein the resistor is connected in parallel to the battery cell; and
a disconnected state wherein the resistor is disconnected from the battery cell; and
an ammeter, wherein the string fuse, the at least one parallel arrangement and the ammeter of each additional string are connected in series; and
for each additional string, the method further comprises determining a state of the string fuse of the additional string by:
changing the at least one parallel arrangement of the additional string to the connected state;
measuring a current passing through the additional string using the ammeter of the additional string during an additional time period after changing the at least one parallel arrangement of the additional string to the connected state;
determining whether a change in the current during the additional time period is greater than a threshold current change;
in an event that the change in the current during the additional time period does not exceed the threshold change, providing a notification that the string fuse of the additional string is in a blown state; and
wherein in an event that the change in the current during the additional time period is greater than the threshold change, the string fuse of the additional string is determined to be intact.

6. The method of claim 5, wherein each string comprises more than one parallel arrangement.

7. The method of claim 4 wherein determining the state of the first string fuse and determining the state of the second string fuse occur sequentially.

8. The method of claim 5 wherein determining the state of the first string fuse, second string fuse and the string fuse of each additional string occurs sequentially.

9. The method of claim 1, wherein determination of the state of the first string fuse is carried out when the battery pack is in standby mode.

10. The method of claim 8, wherein determination of the state of the first string fuse, the second string fuse and the third string fuse is carried out when the battery pack is in standby mode

11. The method of claim 9, wherein the battery pack is configured to power an electric vehicle and wherein the method is carried out at a key ON state of the electric vehicle.

12. The method of claim 1, further comprising comparing a current of each connected string of the battery pack string to a current of the battery pack, wherein in an event that for a period of time longer than a threshold time the current of the battery pack is above a pack threshold and the current of the connected string is below a string threshold the method further comprises providing a notification that the string fuse of the string is in a blown state.

13. The method of claim 1 wherein the battery pack further comprises a battery pack fuse, the method further comprising determining a status of the battery pack fuse by comparing a bus voltage and a battery pack voltage, wherein in an event that a difference between the bus voltage and the battery pack voltage is above a voltage threshold for a period of time longer than a threshold time, the method further comprises providing a notification that the battery pack fuse is in a blown state.

14. The method of claim 1 wherein the battery pack further comprises a battery pack fuse and wherein the battery pack is included in a multi-pack battery comprising at least one additional battery pack, the method further comprising comparing a current of each connected battery pack of the multi-pack battery to a current of the multi-pack battery, wherein in an event that the current of the multi-pack battery is above a battery current threshold and the current of the battery pack is below a pack current threshold, the method further comprises notifying an operator that the battery pack fuse is in a blown state.

15. The method of claim 12 wherein the step of comparing a current of each string to a current of the battery pack is carried out continuously while the battery pack is online.

16. The method of claim 1, wherein in an event that a string fuse is in a blown state the method further comprises adjusting a current limit of the battery pack.

17. The method of claim 13, wherein in an event that the battery pack fuse is in a blown state the method further comprises adjusting a current limit of the multi-pack battery.

18. A battery management system configured to carry out the method of claim 1, wherein the battery management system comprises a controller communicably coupled to the at least one parallel arrangement and the first ammeter.

19. A machine comprising:
an electrical load;
a battery pack coupled to the electrical load, the battery pack comprising:
a first string comprising:
a first string fuse;
at least one parallel arrangement comprising a battery cell and a resistor, wherein the parallel arrangement is configured to be changeable between:
a connected state wherein the resistor is connected in parallel to the battery cell; and
a disconnected state wherein the resistor is disconnected from the battery cell; and
a first ammeter, wherein the first string fuse, the at least one parallel arrangement and the first ammeter are connected in series; and
a second string connected in parallel to the first string, the second string comprising at least one battery cell; and
a battery management system configured to carry out the method of claim 1.

20. A method of detecting the presence or absence of an open circuit in a battery pack, wherein the battery pack comprises:
a first string comprising:
at least one parallel arrangement comprising a battery cell and a resistor, wherein the parallel arrangement is configured to be changeable between:
a connected state wherein resistor is connected in parallel to the battery cell; and
a disconnected state wherein the resistor is disconnected from the battery cell; and
a first ammeter, wherein the at least one parallel arrangement and the first ammeter are connected in series; and
a second string connected in parallel to the first string, the second string comprising at least one battery cell;
the method comprising:
changing the at least one parallel arrangement to the connected state;
measuring a first current passing through the first string using the first ammeter during a first time period after the at least one parallel arrangement is changed to the connected state;
determining whether a change in the first current during the first time period is greater than a threshold current change; and
in an event that the change in the first current during the first time period does not exceed the threshold change, providing a notification that the first string comprises a break in the circuit;
wherein in an event that the change in the first current during the first time period is greater than the threshold change, the first string is determined to be intact.
